(19) United States
(12) Patent Application Publication
(10) Pub. No.: US 2007/0290203 A1
(43) Pub. Date: Dec. 20, 2007

(54) SEMICONDUCTOR ELEMENT AND METHOD OF MANUFACTURING THE SAME

(75) Inventor: Ryo SAEKI, Tokyo (JP)

Correspondence Address: BANNER & WITCOFF, LTD.;ATTORNEYS FOR CLIENT NO. 000449, 001701, 1100 13th STREET, N.W., SUITE 1200, WASHINGTON, DC, 20005-4051, US

(73) Assignee: KABUSHIKI KAISHA TOSHIBA, Tokyo (JP)

(21) Appl. No.: 11/616,649

(22) Filed: Dec. 27, 2006

(30) Foreign Application Priority Data
Dec. 27, 2005 (JP) P2005-374565

(51) Int. Cl. H01L 33/00

(52) U.S. Cl. 257/43; 438/47; 257/E33.014

(57) ABSTRACT

In one aspect, a semiconductor element may include a first substrate made of a N-type ZnO substrate, a P-type semiconductor layer provided on the first substrate, the P-type semiconductor layer having a nitride-based semiconductor, a lamination member provided on the P-type semiconductor layer, lamination member having a nitride-based semiconductor, and a N-type semiconductor layer in the uppermost layer, a first electrode provided on the lamination member, and a second electrode provided on the first substrate.

### CROSS REFERENCE TO RELATED APPLICATION

This application is based upon and claims the benefit of priority from Japanese Patent Application No. 2005-374565, filed on Dec. 27, 2005, the entire contents of which are incorporated herein by reference.

### BACKGROUND

A ZnO substrate, which has a high electric mobility, is known as a growth substrate for growing nitride-based semiconductor. However, it is difficult to obtain a P-type ZnO substrate, since activating P-type ZnO is difficult.

### SUMMARY

Aspects of the invention relate to an improved semiconductor element and an improved method of manufacturing a semiconductor element.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings.

FIG. 1 is a cross sectional view of a semiconductor element in accordance with a first embodiment.

FIG. 2A and FIG. 2B are energy band diagrams of a junction between an N-type ZnO 40 and a P-type GaN 44.

FIG. 3 is a cross sectional view of a semiconductor element in accordance with a comparative example.

FIG. 4 is a cross sectional view of the semiconductor element showing a part of a manufacturing process in accordance with a first embodiment.

FIGS. 5A-5F are cross sectional views of the semiconductor element showing a part of a manufacturing process in accordance with a first embodiment.

FIG. 6 is a flow chart showing a manufacturing process of the semiconductor element in accordance with a first embodiment.

FIG. 7 is a cross sectional view of a semiconductor element in accordance with a second embodiment.

FIG. 8 is a cross sectional view showing a wafer bonding process of a semiconductor element in accordance with a second embodiment.

FIG. 9 is a flow chart showing a wafer bonding process of the semiconductor element in accordance with a second embodiment.

FIG. 10 is a cross sectional view of a semiconductor element in accordance with a first modification of the second embodiment.

FIG. 11 is a cross sectional view of a semiconductor element in accordance with a second modification of the second embodiment.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as follows.

General Overview

In one aspect of the present invention, a semiconductor element may include a first substrate made of a N-type ZnO substrate, a P-type semiconductor layer provided on the first substrate, the P-type semiconductor layer having a nitride-based semiconductor, a lamination member provided on the P-type semiconductor layer, lamination member having a nitride-based semiconductor and a N-type semiconductor layer in the uppermost layer, a first electrode provided on the lamination member, and a second electrode provided on the first substrate.

In one aspect of the present invention, a semiconductor element may include a first substrate made of a N-type ZnO substrate, a P-type semiconductor layer provided on the first substrate, the P-type semiconductor layer having a nitride-based semiconductor, a lamination member provided on the P-type semiconductor layer, the lamination member having a nitride-based semiconductor, a N-type semiconductor layer in the uppermost layer, and a active layer configured to emit a light, a first electrode provided on the lamination member, and a second electrode provided on the first substrate.

In another aspect of the invention, a method of manufacturing a semiconductor element may include forming a P-type semiconductor layer on a first substrate, adhering a N-type ZnO substrate on the P-type semiconductor layer, forming a second electrode on a bottom surface of the N-type ZnO substrate, removing the first substrate from the P-type semiconductor layer, forming a lamination member on the P-type semiconductor layer, the lamination member having a nitride-based semiconductor and a N-type semiconductor layer in the uppermost layer, and forming a first electrode on the lamination member.

### First Embodiment

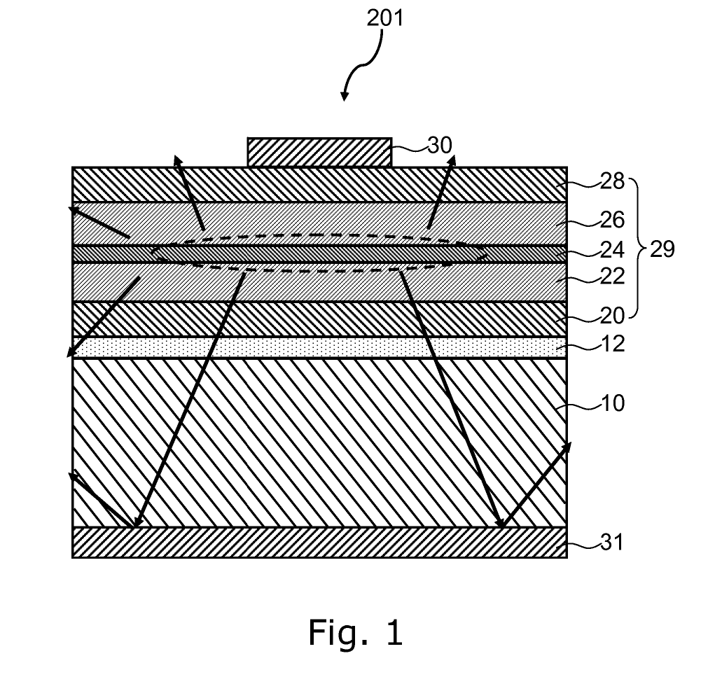

A first embodiment of the present invention will be explained hereinafter with reference to FIGS. 1-2B and FIGS. 4-6.

The nitride-based semiconductor used herein includes semiconductors having any composition represented by the chemical formula BₓIn_{y}Al_{z}Ga_{1-x-y-z}N (0≦x≦1, 0≦y≦1, 0≦z≦1, x+y+z≦1) where the composition ratios x, y and z are varied in the respective ranges. Furthermore, the nitride-based semiconductor may or may not also include any of various impurities added for controlling conductivity types.

FIG. 1 is a cross-sectional view of a semiconductor element 201 in accordance with a first embodiment. In this first embodiment, the semiconductor element 201 is a semiconductor light emitting element. As in FIG. 1, a P-type low resistance layer 12, such as P-type GaN (thickness: 0.2-0.5 micrometers), is provided on an N-type ZnO substrate 10. A lamination member 29 is provided on the P-type low resistance layer 12. A P-type GaN layer 20 (thickness: 0.1-0.4 micrometers), a P-type cladding layer 22 (thickness: 0.5-1.0 micrometers), which may be made of a P-type InGaAlN, an active layer 24 (thickness: 0.05-0.2 micrometers), which may be made of InGaAlN MQW (Multi Quantum Well), an N-type cladding layer 26 (thickness: 0.5-1.0 micrometers), which may be made of InGaAlN, and a contact layer 28 (thickness: 1.0-4.0 micrometers), which may be made of N-type GaN, are provided in the lamination member 29. A first electrode 30 is provided on the lamination member 29. A second electrode 31 is provided on the N-type ZnO substrate 1O.

A current is injected from the second electrode 31 and reaches the first electrode 30 via the low resistance layer 12 and the lamination member 29. In the active layer 24, the holes and electrons are recombined. As a result, light is emitted from the active layer 24. In at least one aspect of the present invention, it may be preferable that an area of the contact layer 28 is larger than the area of the first electrode 30 in order to obtain a high optical output.

The band gap of the N-type ZnO substrate 10 may be about 3.37 eV, and the band gap wavelength of the N-type ZnO substrate 10 may be about 368 nanometers. A light having longer wavelength than this band gap wavelength is minimally absorbed (or in some aspects, not absorbed) by the N-type ZnO substrate 10 and emitted outward through the N-type ZnO substrate 10. The band gap of no less than about 368 nanometers contains almost all of the visible light longer than violet light. So a high optical output may be obtained in this wavelength band.

Next, the following describes the function of the junction between the P-type low resistance layer 12 and the N-type ZnO substrate 10. In at least one aspect of the present invention, it may be preferable that the conductivity type of the contact layer 28 is N-type.

In this embodiment, the N-type cladding layer 26 is provided on the upper surface of the active layer 24, and the P-type cladding layer 22 is provided on the bottom surface of the active layer 24. The P-type low resistance layer 12 is provided between the P-type GaN layer 20 and the N-type ZnO substrate 10. The direction of the PN junction between the P-type GaN layer 20 and the N-type ZnO substrate 10 is opposite to the direction of the PN junction in the lamination member 29. In other words, in this semiconductor light emitting element 201, an NPN junction is provided. However, the PN junction between the P-type GaN layer 20 and the N-type ZnO substrate 10 has low contact resistance (low ohmic contact).

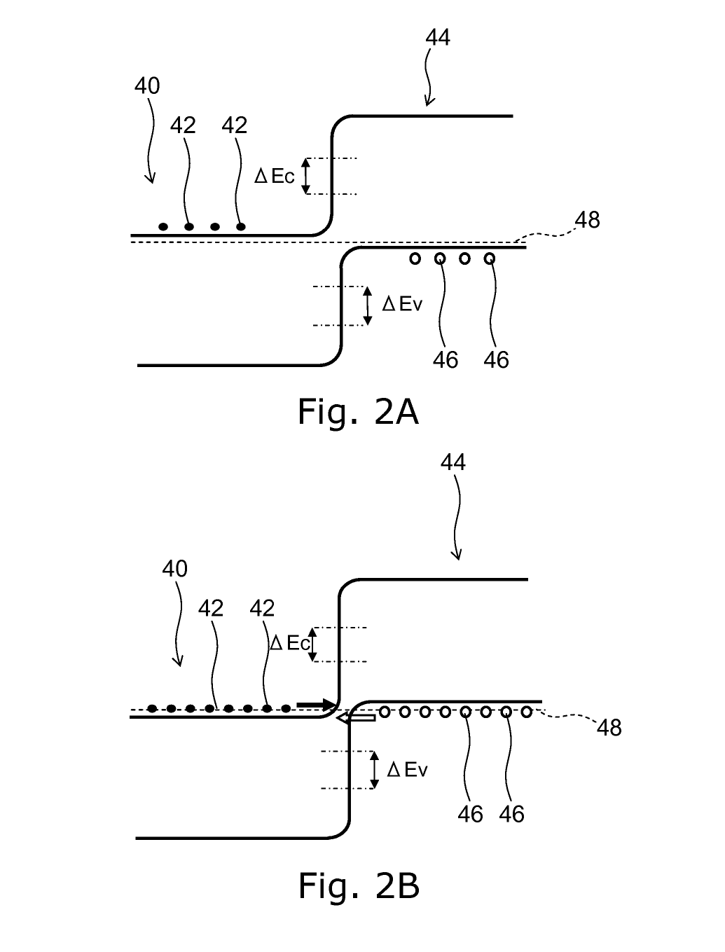

FIG. 2A is an energy band diagram of a junction between an N-type ZnO 40 and a P-type GaN 44, when the carrier concentration in the PN junction is no more than 1×10¹⁸ cm⁻³. The band gap energy of the N-type ZnO 40 and the P-type GaN 44 are about 3.3-3.4 eV, respectively. Namely, the band gap of the N-type ZnO 40 and the P-type GaN 44 are close. In a thermal equilibrium state, the PN junction between the N-type ZnO 40 and the P-type GaN 44 are provided such that both of the Fermi Levels 48 are coincident. The band discontinuity of conduction band ΔE_{C} and the band discontinuity of valence band ΔEᵥ are about 0.8 eV, respectively. In case there is a relative wide band discontinuity, an energy spike does not occur between the N-type ZnO 40 and the P-type GaN 44. In this case, the PN junction has general characteristics of PN junction, such as the current hardly flows (if at all) from the N-type semiconductor layer to the P-type semiconductor (if at all). In other words, the current hardly flows (if at all) from the P-type GaN layer 44 to the N-type ZnO substrate 40.

FIG. 2B is an energy band diagram of a junction between an N-type ZnO 40 and a P-type GaN 44, when the carrier concentration in the PN junction is no less than 5×10¹⁸ cm⁻³. As shown in FIG. 2B, when the carrier concentration is large, the width of the depletion layer is small and the tunneling current is increased. When the carrier concentration in the PN junction is 1×10¹⁹ cm⁻³, the width of the depletion layer is no more than 20 nm, and the tunnel effect may occur without increasing the voltage. Thus, the desired ohmic contact may be obtained.

There are many ways to provide a P-type low resistance layer 12 on the N-type ZnO substrate 10. In each way, high temperature processing may be needed for crystal growing or wafer bonding process. During such a high temperature process, Ga, In or Al from the P-type low resistance layer 12 having GaN, InGaN, InGaAlN or GaAlN, may be diffused to N-type ZnO substrate 10 through the boundary. Zn from the N-type ZnO substrate 10 may be diffused to the P-type low resistance layer 12. The desired ohmic contact may be formed by such a high temperature process.

In at least one aspect of the present invention, it may be preferable that the donor concentration of the N-type ZnO substrate 10 is no less than 5×10¹⁸ cm⁻³ near the boundary to the P-type low resistance layer 12. It may be more preferable that the donor concentration of the N-type ZnO substrate 10 is no less than 5×10¹⁹ cm⁻³ near the boundary to the P-type low resistance layer 12. At the same time, it may be preferable that the acceptor concentration of the P-type low resistance layer 12 is no less than 5×10¹⁸ cm⁻³ near the boundary to the N-type ZnO substrate 10. It may be more preferable that the acceptor concentration of the P-type low resistance layer 12 is no less than 5×10¹⁹ cm⁻³ near the boundary to the N-type ZnO substrate 10.

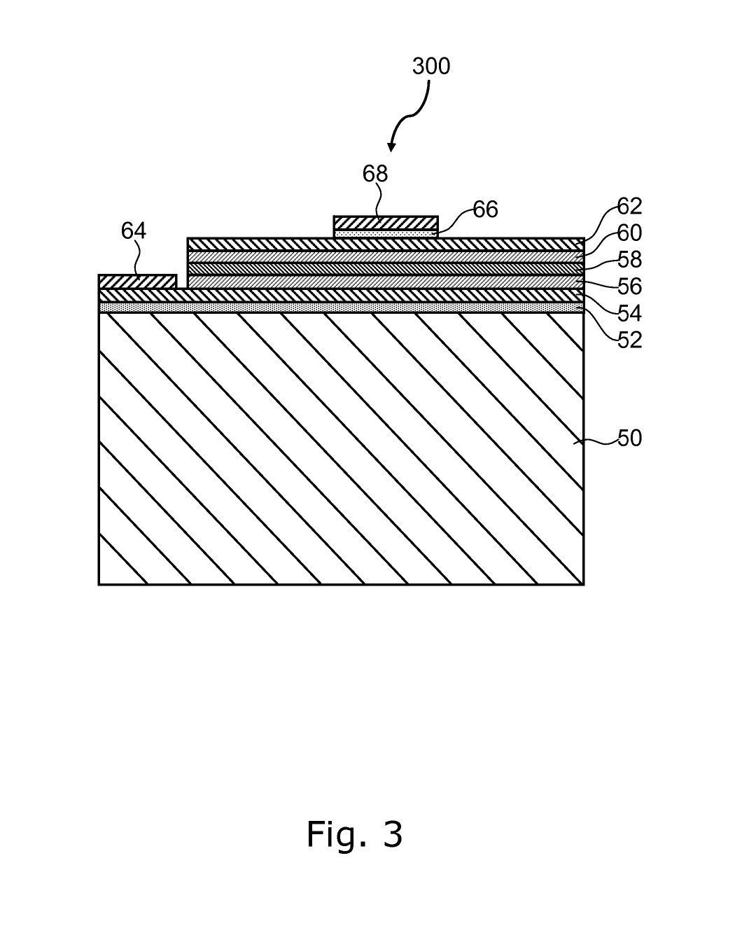

FIG. 3 is a cross sectional view of a semiconductor element in accordance with a comparative example, in which a sapphire substrate 50 is used.

A low temperature growing AlN buffer layer 52, an N-type GaN layer 54, an N-type InGaAlN cladding layer 56, an active layer 58 having InGaAlN MQW structure, a P-type InGaAlN cladding layer 60, and a P-type GaN layer 62 are grown on the sapphire substrate 50 in this order. A P-side electrode 68 is provided on the P-type GaN layer 62 via a P+ GaN contact layer 66. A part of the N-type GaN layer 54 is exposed. An N-side electrode 64 is provided on the exposed GaN layer 54.

A current injected from the P-side electrode 68 is spread laterally in the P-type GaN layer 62. The current flows to the N-side electrode 64 through the P-type cladding layer 60, the active layer 58, N-type cladding layer 56 and the N-type GaN layer 54. Green light, blue light, or ultraviolet light is generated by recombination of the electrons and holes.

The thickness of the semiconductor lamination, which is formed on the sapphire substrate 50, is about some micrometers, which is relatively thin. The sheet resistance of the semiconductor lamination is high, and the serial resistance of the current passed between the semiconductor lamination and the N-side electrode 64 is high. Thus, the optical emission efficiency may be decreased because of increasing temperature when a large current such as some hundred mA flows from the P-side electrode 68. Furthermore, the optical emission efficiency may be worsened, since the heat conductivity ratio of the sapphire substrate is not high and the current in the in-plane distribution is uneven at the high current. In addition, it is hard to form the N-side electrode 64 on the N-type GaN layer 54.

On the other hand, in the first embodiment as shown in FIG. 1, the P-side electrode 31 may be provided on whole surface of the N-type ZnO substrate 10. Thus, the serial resistance may be decreased. It may be possible for the semiconductor element 201 to be operated with a high current. And the heat conductivity ratio of the ZnO is about 1.5 times than that of the sapphire substrate. It may be easier to form an electrode on the bottom surface of the substrate as in FIG. 1 than the N-side electrode as in FIG. 3. So, throughput for manufacturing a light emitting element may be improved.

Next, the N-type ZnO substrate 10 in the first embodiment may be explained hereinafter. Light having a wavelength longer than the band gap wavelength of the ZnO (about 368 nanometers) may be not absorbed by the ZnO substrate 10. So high optical extraction efficiency may be obtained.

The ZnO may have a Wurtuite structure, which is the same crystal structure as the GaN. The lattice constant of the ZnO is similar to that of the GaN. For example, the lattice mismatch between the sapphire and the GaN is no less than 10%. The lattice mismatch between the ZnO and the GaN is no more than 4%, which is small. So the crystal distortion may be decreased, and the warp of the semiconductor lamination or crack in the semiconductor lamination may be decreased. So one or more characteristics of the GaN-based semiconductor, provided on the ZnO substrate, may be improved.

Furthermore, the ZnO substrate has a better heat conductivity efficiency than the sapphire substrate. The sapphire has 0.4 W/(K·cm), and the ZnO has 0.6 W/(K·cm). Namely, the heat conductivity efficiency of the ZnO is about 1.5 times than that of the sapphire. So the ZnO substrate may be suitable for light emitting device for a high optical output, or a power semiconductor device.

Next, the manufacturing process of the P-type low resistance layer 12 on the N-type ZnO substrate 10 will be explained hereinafter. The manufacturing process may use vapor phase growing or wafer bonding processes.

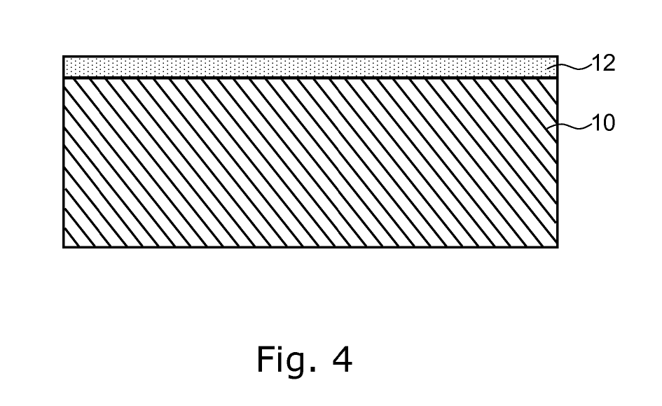

As shown in FIG. 4, the P-type low resistance layer 12 is grown on the N-type ZnO substrate 10 by, for example, MOCVD (Metal Organic Chemical Vapor Deposition) method. The P-type low resistance layer 12 may be a P-type GaN, a P-type InGaN, a P-type InGaAlN, a P-type GaAlN or the like. A raw material may be ammonia, TMI (Tri-Methyl Indium), TMA (Tri-Methyl Aluminum), TMG (Tri-Methyl Gallium), Cp2Mg, or the like. The growing temperature may be 900-1200 Centigrade. In that temperature range, it may be sufficient that Ga and In are diffused to the ZnO substrate 10. At the same time, it may be sufficient that Zn is diffused to the P-type low resistance layer 12. Thus, a region, in which the acceptor concentration and donor concentration is no less than 5×10 cm⁻³, may be provided near the boundary between the N-type ZnO substrate 10 and the P-type low resistance layer 12. So the PN junction having a low resistance and ohmic contact may be obtained.

Alternatively, the P-type low resistance layer 12 may be grown on the N-type ZnO substrate 10 by VPE (Vapor Phase Epitaxy) method. The P-type low resistance layer 12 may preferably be a P-type GaN or a P-type InGaN. A raw material may be ammonia, Ga, In, H₂Cl or the like. The growing temperature may preferably be 900-1200 Centigrade. In that temperature, it may be sufficient that Ga and In are diffused to the ZnO substrate 10. At the same time, it may be sufficient that Zn is diffused to the P-type low resistance layer 12. Thus, a region, in which the acceptor concentration and donor concentration is no less than 5×10¹⁸ cm⁻³, may be provided near the boundary between the N-type ZnO substrate 10 and the P-type low resistance layer 12. So the PN junction having a low resistance and ohmic contact may be obtained.

Alternatively, the P-type low resistance layer 12 may be grown on the N-type ZnO substrate 10 by MBE (Molecular Beam Epitaxy) method. A raw material for Group III may be Ga, In, Al, TMG, TMA, TMA or the like. A raw material for Group V may be nitrogen, tertiary butyl amine, Dimethylhydrazine, ammonia, or the like. A raw material for P-type impurity may be Mg, Cp2Mg, or the like. The growing temperature may preferably be 600-900 Centigrade. A region, in which the acceptor concentration and donor concentration is no less than 5×10¹⁸ cm⁻³, may be provided near the boundary between the N-type ZnO substrate 10 and the P-type low resistance layer 12. So the PN junction having a low resistance and ohmic contact may be obtained.

Thus a PN junction, which has high carrier concentration, may be provided, and the carrier is tunneled through the boundary of the PN junction. So ohmic contact and low resistance may be obtained.

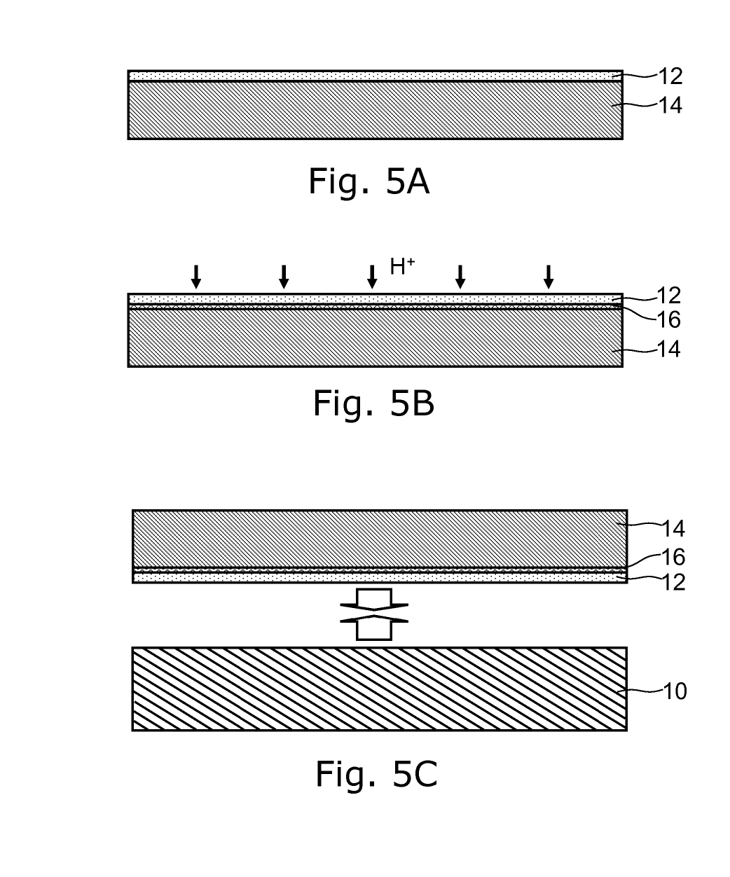

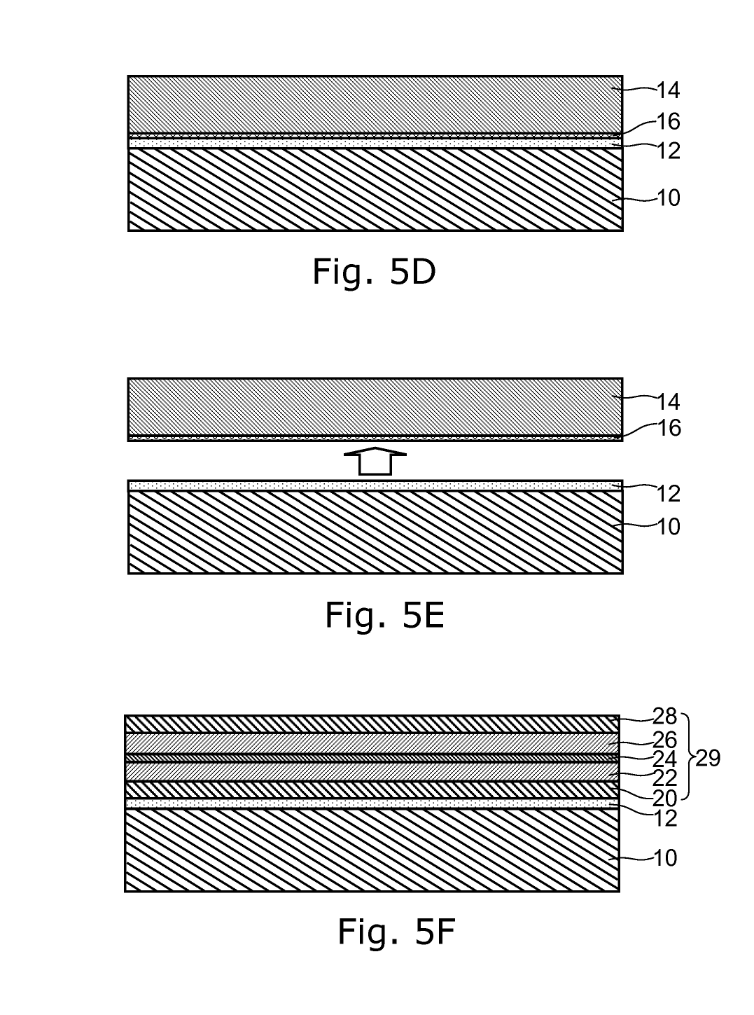

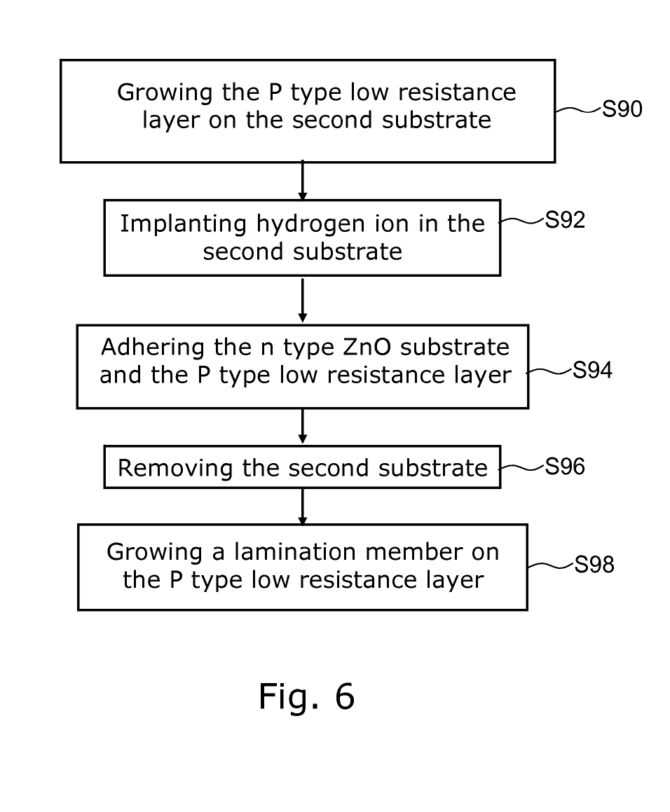

Next, wafer bonding process may be explained hereinafter with reference to FIGS. 5A-5F and FIG. 6.

Step S90. Growing the P-type low resistance layer on the second substrate.

As shown in FIG. 5A, the P-type low resistance layer 12, which is GaN, InGaAlN, InGaAlN, GaAlN, or the like, is grown on the second substrate 14, such as N-type GaN substrate. The thickness of the P-type low resistance layer 12 may be about 0.2-5.0 micrometers. The P-type low resistance layer 12 may be grown by MOCVD method, VPE method, MBE method, or the like.

The upper surface of the P-type low resistance layer 12 is polished mechanically and/or chemically.

Step S92. Implanting hydrogen ion in the second substrate.

Hydrogen ion H⁺⁺ is introduced into near the boundary between the second substrate 14 and the P-type low resistance layer 12 by ion implanting. So a hydrogen implanted layer 16 is provided on the second substrate 14 and under the P-type low resistance layer 16. It may be preferable that the hydrogen implanted layer 16 is provided on the boundary between the second substrate 14 and the P-type low resistance layer 12, and most of the hydrogen is implanted in the second substrate 14. FIG. 5B is a cross sectional view after the hydrogen is implanted.

The implanting ion is not limited to hydrogen. Nitrogen ion or oxygen ion may be used as the implanting ion.

An operating condition of ion implanting is explained. When an implanting energy is small, the implanted layer is not provided in a deep position. When an implanting energy is large, the damage by ion implanting is large. So, the implanting energy may preferably be 5-500 keV When the dose is small, it is hard to obtain a mechanical weak layer. When the dose is large, the damage by ion implanting is large is high. So, the dose may preferably be 5×10¹⁵-1×10¹⁹ cm⁻².

Step S94. Adhering the N-type ZnO substrate and the P-type low resistance layer.

A surface of the P-type low resistance layer 12, which is provided above the second substrate 14, and a surface of an N-type ZnO substrate 10 are adhered with wafer state. This wafer bonding process is operated as follows. Mirrors surface of the wafers are adhered by surface tension, and adhered wafers are heated in inert atmosphere. The wafer bonding process may be operated in about 600 Centigrade for about 1 hour. FIG. 5C is a cross sectional view before wafer bonding, and FIG. 5D is a cross sectional view after wafer bonding

Step S96. Removing the second substrate.

The bonded wafer is separated along the hydrogen implanted layer 16. The region, which hydrogen is implanted, has low mechanical strength, since the region has amorphous crystal structure. So two semiconductor lamination members are provided. One semiconductor lamination member (bottom member in FIG. 5E) is the P-type low resistance layer 12 and the N-type ZnO substrate 10. The other semiconductor lamination member (upper member in FIG. 5E) is the second substrate 14 and the hydrogen implanted layer 16. FIG. 5E is a cross sectional view after the second substrate 14 with the hydrogen implanted layers 16 being separated from the low resistance layer 16 on the ZnO substrate 10.

The bonded wafer may be easily separated by heat operation or mechanical impact. Alternatively the bonded wafer may be separated by natural peeling in heating or cooling. Alternatively, laser or water jet may be irradiated in a side face of the bonded wafer for separating.

Step S98. Growing a lamination member on the P-type low resistance layer.

The N-type ZnO substrate 10 with P-type low resistance layer 12 is heated for about 2 hours in about 700-900 Centigrade. During this heat operation. Ga, In, or Al is diffused toward the N-type ZnO substrate 10. During this heat operation. Zn is diffused toward the P-type low resistance layer 12. A region, in which the donor concentration and acceptor concentration is no more than 1×10¹⁹ cm⁻³, is provided. So the PN junction having low resistance and ohmic contact is obtained.

The separated second substrate 14 may be used again for being grown on by the other P-type low resistance layer 16 so as to manufacture other semiconductor element.

As shown in FIG. 5F, the lamination member 29 is provided on the P-type low resistance layer 12. The lamination member 29 may be formed by MOCVD method, VPE method, MBE method or the like. Later that, the first electrode 30 and the second electrode are provided. Then wafer is separated into a plurality of semiconductor light emitting chips.

The second substrate 14 is not limited to N-type GaN. The second substrate 14 may be sapphire, SiC, GaAs, or the like.

In case the sapphire substrate or SiC substrate is used as the second substrate 14, the thickness of the P-type low resistance layer 12 may be thicker than that in the GaN substrate. The thickness may be 0.2-10.0 micrometers.

In case the GaAs substrate is used as the second substrate 14, the removing second substrate (GaAs) may be in about 750-900 Centigrade.

### Second Embodiment

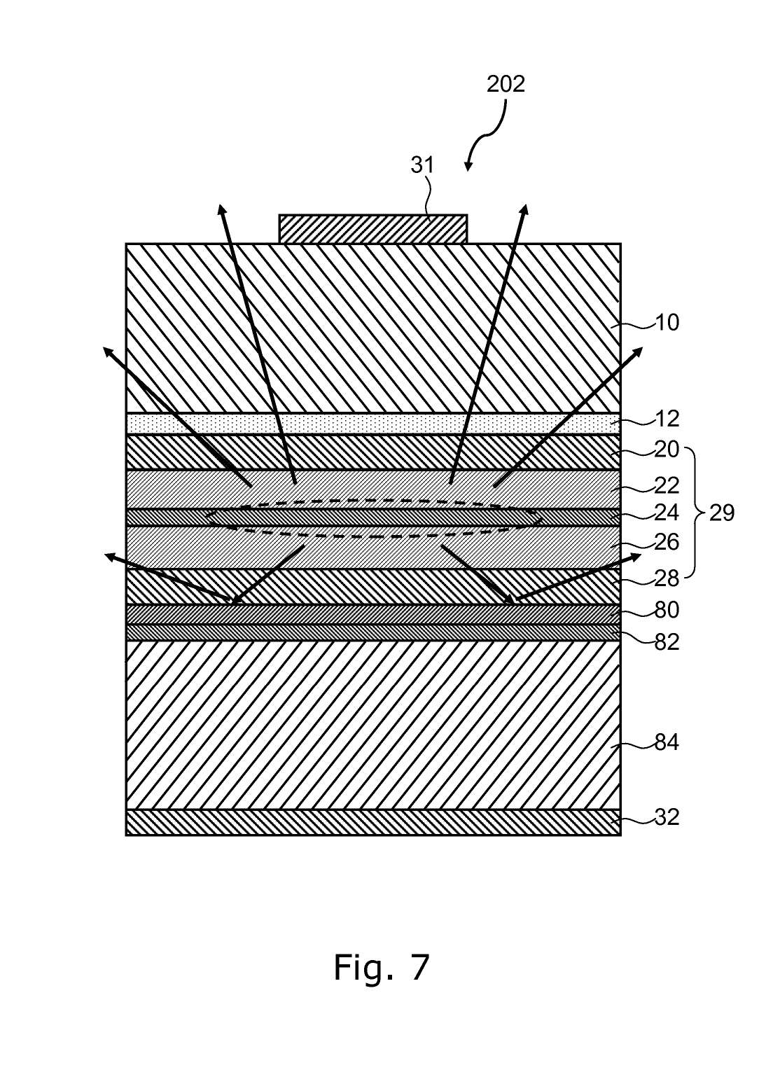

A second embodiment is explained with reference to FIGS. 7-9.

A semiconductor element 202 is described in accordance with a second embodiment of the present invention. With respect to each portion of this embodiment, the same or corresponding portions of the semiconductor element of the first embodiment shown in FIGS. 1-6 are designated by the same reference numerals, and explanation of such portions is omitted.

As shown in FIG. 7, a first metal layer 80, which is made of Au-based metal and has several micrometers, is provided on the N-type GaN layer 28, which is uppermost layer (lowermost layer in FIG. 7) in the lamination member 29. A second metal layer 82, which is made of Au-based metal and has several micrometers, is provided on a substrate 84. The first metal layer 80 and the second metal layer 82 are bonded each other, and the semiconductor element 202 as shown in FIG. 7 is provided. A third electrode 32 is provided on the substrate 84. The first metal layer 80 may has high reflection index and low electric resistance.

The substrate 84 may be Si, SiC, C, CuW, diamond or the like, which has high heat conductivity.

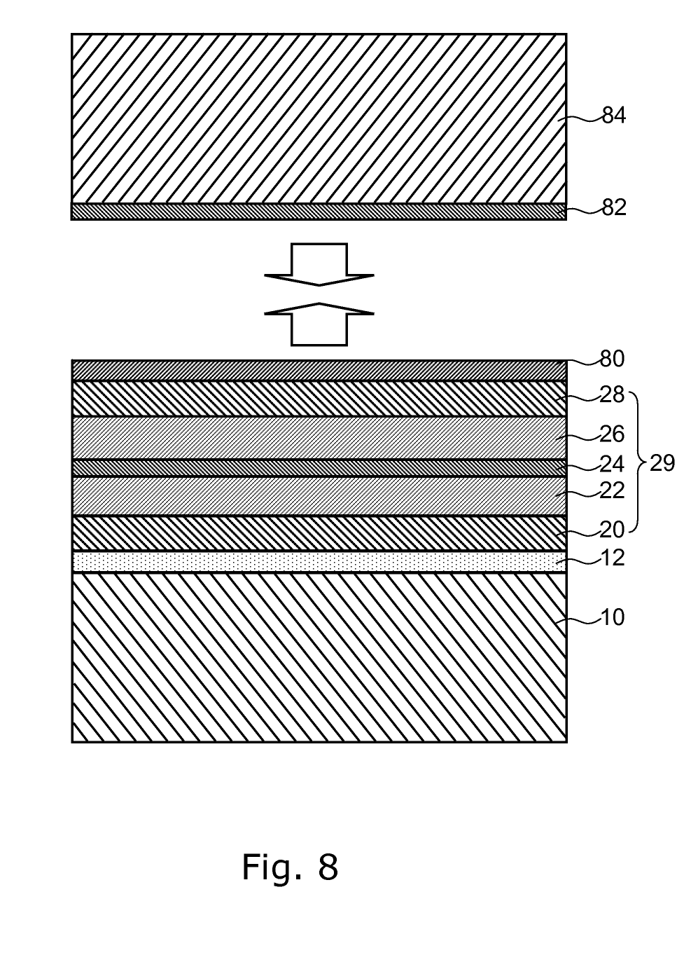

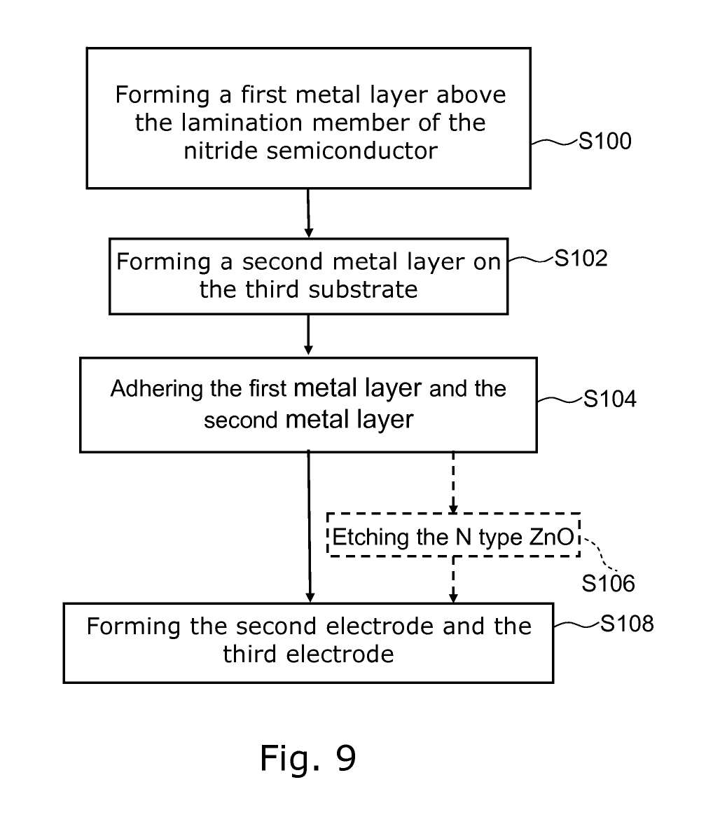

The bonding process for the first metal layer 80 and the second metal layer 82 is explained with reference to FIGS. 8 and 9.

Step S100. Forming a first metal layer above the lamination member of the nitride semiconductor.

The first metal layer 80 is provided on the semiconductor lamination member 29.

Step S102. Forming a second metal layer on the substrate

The second metal layer 82 is provided on the substrate 84.

Step S104. Adhering the first metal layer and the second metal layer.

The first metal layer 80 and the second metal layer 82 are adhered by surface tension.

Step S 108. Forming the second electrode and the third electrode.

The adhered semiconductor lamination is heated in about 600 Centigrade inert atmosphere for about an hour. So the first metal layer 80 and the second metal layer 82 are bonded.

As shown in Step S106, the N-type ZnO may be thinned. The band gap wavelength of the GaN-based semiconductor is close to or a little smaller than that of the ZnO. So the emission light from the active layer 24 may be attenuated in the ZnO substrate 10, and optical output efficiency may be decreased. In order to avoiding attenuation, the ZnO substrate 10 may be thinned as shown in Step S106. The ZnO substrate 10 may be thinned by chemical and/or mechanical polishing, or by wet etching. It may be preferable that the thickness of the ZnO substrate 10 is 0-150 micrometers.

### A First Modification of the Second Embodiment

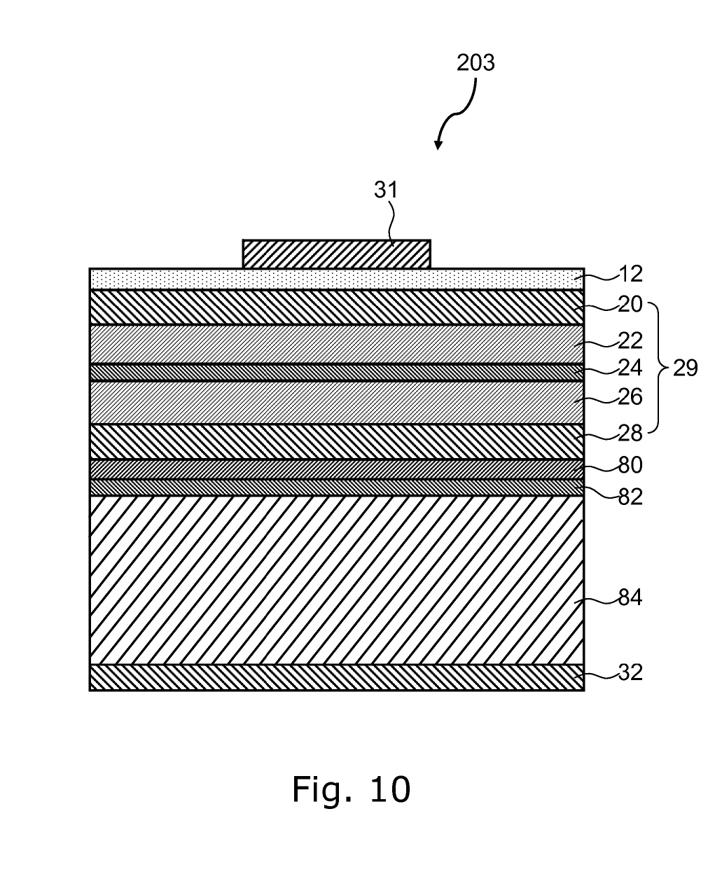

A first modification of the second embodiment will be explained with reference to FIG. 10.

As shown in FIG. 10, the ZnO substrate 10 may be removed from the semiconductor element 203. In this semiconductor light emitting element 203, optical output efficiency may be greater than the semiconductor light emitting element 202 as shown in FIG. 7.

### A Second Modification of the Second Embodiment

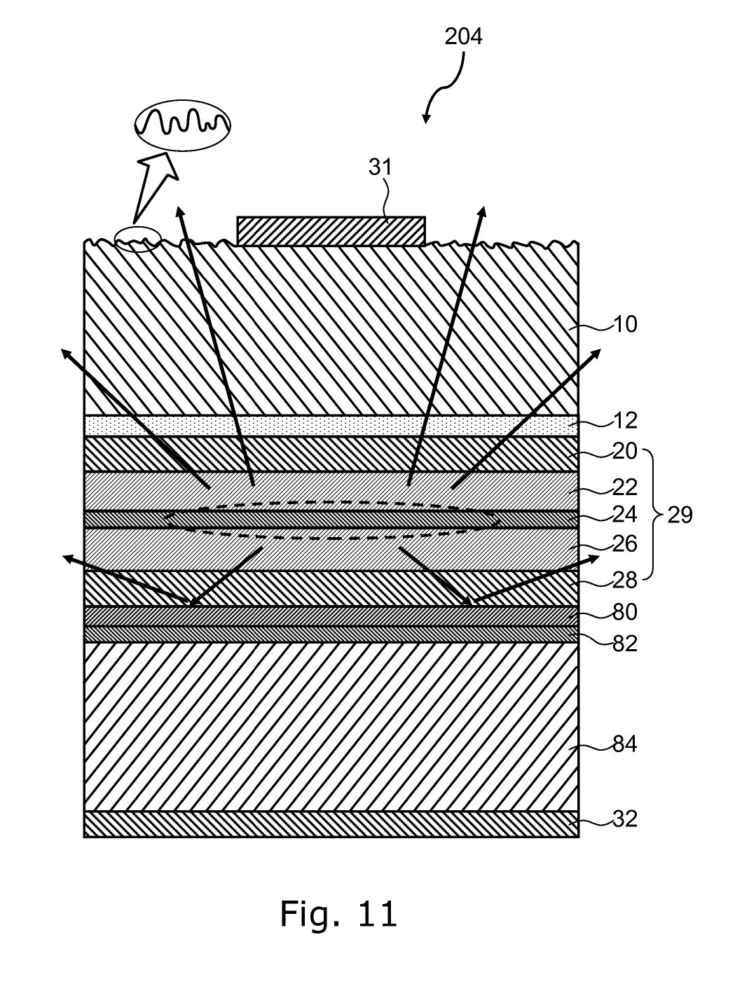

A second modification of the second embodiment will be explained with reference to FIG. 11.

In this semiconductor light emitting element 204, the upper surface of the N-type ZnO substrate 10 may be roughened. In the semiconductor light emitting element 204, light from the active layer 24 to downward is reflected by the first metal layer 80, and extracted from the side surface and upper surface of the semiconductor light emitting element 204. In the semiconductor light emitting element 204, the optical out put efficiency may be improved with comparing to the semiconductor light emitting element 203 as in FIG. 10, since the upper surface of the ZnO substrate 10 is roughened and total reflection is reduced.

The upper surface of the ZnO substrate 10 may be roughened by wet etching using hydrochloric acid or acetic acid. Fine protrusion having 0.1-10 micrometers in height are provided by controlling the density and/or the temperature of the etchant.

Embodiments of the invention have been described with reference to the examples. However, the invention is not limited thereto.

For example, the invention is not limited to light emitting element. This invention is applicable to power semiconductor element such as FET, which is capable of being used in high temperature. The heat conduction efficiency may be improved, since the heat conductivity efficiency of the ZnO substrate is 1.5 times than that of sapphire. Furthermore, this invention may be applicable to HEMT (high Electron Mobility Transistor) or HBT (Hetero Bipolar Transistor).

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A semiconductor element, comprising:
a first substrate made of an N-type ZnO substrate;
a P-type semiconductor layer provided on the first substrate, the P-type semiconductor layer having a nitride-based semiconductor;
a lamination member provided on the P-type semiconductor layer, the lamination member having a nitride-based semiconductor and an N-type semiconductor layer in the uppermost layer;
a first electrode provided on the lamination member; and
a second electrode provided on the first substrate.

2. A semiconductor element of claim 1, wherein a carrier concentration in the junction between the first substrate and the P-type semiconductor layer is no less than 5×10¹⁸ cm⁻³.

3. A semiconductor element of claim 1, wherein a donor concentration of the first substrate is no less than 5×10¹⁸ cm⁻³.

4. A semiconductor element of claim 1, wherein an acceptor concentration of the P-type semiconductor layer is no less than 5×10¹⁸ cm⁻³.

5. A semiconductor element of claim 3, wherein an acceptor concentration of the P-type semiconductor layer is no less than 5×10¹⁸ cm⁻³.

6. A semiconductor element of claim 1, wherein the lamination member has a P-type semiconductor layer in the lowermost layer.

7. A semiconductor element, comprising:
a first substrate made of an N-type ZnO substrate;
a P-type semiconductor layer provided on the first substrate, the P-type semiconductor layer having a nitride-based semiconductor;
a lamination member provided on the P-type semiconductor layer, the lamination member having a nitride-based semiconductor, a N-type semiconductor layer in the uppermost layer, and a active layer configured to emit a light;
a first electrode provided on the lamination member; and
a second electrode provided on the first substrate.

8. A semiconductor element of claim 7, wherein a carrier concentration in the junction between the first substrate and the P-type semiconductor layer is no less than 5×10¹⁸ cm⁻³.

9. A semiconductor element of claim 7, wherein a donor concentration of the first substrate is no less than 5×10¹⁸ cm⁻³.

10. A semiconductor element of claim 7, wherein an acceptor concentration of the P-type semiconductor layer is no less than 5×10¹⁸ cm⁻³.

11. A semiconductor element of claim 9, wherein an acceptor concentration of the P-type semiconductor layer is no less than 5×10¹⁸ cm⁻³.

12. A semiconductor element of claim 7, wherein the lamination member has a P-type semiconductor layer in the lowermost layer.

13. A semiconductor element of claim 7, wherein a metal layer configured to reflect light from the active layer is provided on the lamination member.

14. A method of manufacturing a semiconductor element comprising:
forming a P-type semiconductor layer on a first substrate;
adhering an N-type ZnO substrate on the P-type semiconductor layer;
forming a second electrode on a bottom surface of the N-type ZnO substrate;
removing the first substrate from the P-type semiconductor layer;
forming a lamination member on the P-type semiconductor layer, the lamination member having a nitride-based semiconductor and a N-type semiconductor layer in the uppermost layer; and
forming a first electrode on the lamination member.

15. A method of manufacturing a semiconductor element of claim 14, said forming a lamination member results in the lamination member having an active layer configured to emit light.

16. A method of manufacturing a semiconductor element of claim 14, wherein a carrier concentration in the junction between the first substrate and the P-type semiconductor layer is no less than 5×10¹⁸ cm⁻³.

17. A method of manufacturing a semiconductor element of claim 14, wherein a donor concentration of the first substrate is no less than 5×10¹⁸ cm⁻³.

18. A method of manufacturing a semiconductor element of claim 14, wherein an acceptor concentration of the P-type semiconductor layer is no less than 5×10¹⁸ cm⁻³.

19. A method of manufacturing a semiconductor element of claim 17, wherein an acceptor concentration of the P-type semiconductor layer is no less than 5×10¹⁸ cm⁻³.

20. A method of manufacturing a semiconductor element of claim 14, further comprising:
forming an implanted layer between the P-type semiconductor layer and the first substrate by implanting an ion, wherein the first substrate is removed with the implanted layer.
